(19) United States
(12) Patent Application Publication
(10) Pub. No.: US 2026/0323898 A1
(43) Pub. Date: Oct. 15, 2026

(54) SYSTEM AND METHOD FOR BUILDING AND MODIFYING A CIRCUIT BOARD

(71) Applicant: Lockheed Martin Corporation, Bethesda, MD (US)

(72) Inventors: David Francis Aubin, JR., Bethesda, MD (US); Kenneth Elden Colpritt, Bethesda, MD (US); Neil Arthur Huntemann, Bethesda, MD (US); Alexander Weston Casperson, Bethesda, MD (US); Stephen Edward Fanning, Bethesda, MD (US); Andrew Michael Pastore, Bethesda, MD (US); Sophia Shou Liu, Bethesda, MD (US); William Brian Rude, Bethesda, MD (US); Michael Joseph Tyburski, Bethesda, MD (US); Kendell Moore, Bethesda, MD (US); Arthur K. Bryant, Bethesda, MD (US)

(21) Appl. No.: 19/540,219

(22) Filed: Feb. 13, 2026

Related U.S. Application Data
(60) Provisional application No. 63/786,634, filed on Apr. 10, 2025.

(51) Int. Cl. H05K 13/04; H05K 3/341; H05K 13/08

(52) U.S. Cl. CPC H05K 13/0409; H05K 3/341; H05K 13/0413; H05K 13/043; H05K 13/046; H05K 13/0812

(57) ABSTRACT

Systems and methods related to a robotic arm system configured to iteratively pick up and place an object on a circuit board. One system includes a sensor configured to measure an electrical characteristic of the circuit board, an end effector including a tuning tip configured to physically engage the object, and an electronic processor. The processor is configured to pick up, via the end effector, the object, move, via the end effector, the object to a first location of the circuit board, and place, via the end effector, the object on the first location of the circuit board. The processor is further configured to test, via information from the sensor, a first electrical characteristic of the circuit board and pick up, via the end effector, the object from the first location in response to determining that, based on the testing of the first electrical characteristic, the first location is not suitable.

### CROSS-REFERENCE TO RELATED APPLICATIONS

This application claims priority to U.S. Provisional Application No. 63/786,634, filed Apr. 10, 2025, the entire contents of which are herein incorporated by reference.

### TECHNICAL FIELD

The present disclosure relates generally to the field of building circuit boards, and more specifically to a system and method for building and modifying a circuit board.

### BACKGROUND

The process of tuning a circuit that has either a radio frequency receiver or transmitter requires the precise placement of objects on the circuit. Changing the placement of the objects (for example, electronical components such as integrated circuits (ICs)) on the circuit board may change the radio frequency that the circuit is tuned to receive or transmit. To tune the circuit to the desired frequency, the objects placed on the circuit board may have to be moved a plurality of times. Existing methods for placing and moving these objects on the circuit board include hand placement by a highly skilled and experienced technician working with tweezers.

### SUMMARY

The embodiments disclosed herein are only examples, and the scope of this disclosure is not limited to them. Some embodiments may include all, some, or none of the components, elements, features, functions, operations, or steps of the embodiments disclosed herein. The dependencies or references back in the attached claims are chosen for formal reasons only. However, any subject matter resulting from a deliberate reference back to any previous claims (in particular multiple dependencies) can be claimed as well, so that any combination of claims and the features thereof are disclosed and can be claimed regardless of the dependencies chosen in the attached claims. The subject-matter which can be claimed comprises not only the combinations of features as set out in the attached claims but also any other combination of features in the claims, wherein each feature mentioned in the claims can be combined with any other feature or combination of other features in the claims. Furthermore, any of the embodiments and features described or depicted herein can be claimed in a separate claim and/or in any combination with any embodiment or feature described or depicted herein or with any of the features of the attached claims.

Technical advantages of certain embodiments of this disclosure may include one or more of the following. Certain systems and methods described herein may perform tasks including picking up objects from a circuit board, moving the objects to a different location, and placing the objects on the circuit.

For example, some embodiments relate to a robotic arm system configured to iteratively pick up and place an object on a circuit board. The system includes a sensor configured to measure an electrical characteristic of the circuit board, an end effector including a tuning tip configured to physically engage the object, and an electronic processor. The processor is configured to pick up, via the end effector, the object, move, via the end effector, the object to a first location of the circuit board, and place, via the end effector, the object on the first location of the circuit board. The processor is further configured to test, via information from the sensor, a first electrical characteristic of the circuit board and pick up, via the end effector, the object from the first location in response to determining that, based on the testing of the first electrical characteristic, the first location is not suitable.

As another example, some embodiments relate to a method for operating robotic arm system configured to iteratively pick up and place an object on a circuit board. The method includes picking up, via an end effector including a tuning tip configured to physically engage the object, the object, moving, via the end effector, the object to a first location of the circuit board, and placing, via the end effector, the object on the first location of the circuit board. The method further includes testing, via information from a sensor configured to measure a first electrical characteristic of the circuit board, an electrical characteristic of the circuit board, and picking up, via the end effector, the object from the first location in response to determining that, based on the testing of the first electrical characteristic, the first location is not suitable.

Other technical advantages will be readily apparent to one skilled in the art from the following figures, descriptions, and claims. Moreover, while specific advantages have been enumerated above, various embodiments may include all, some, or none of the enumerated advantages.

### BRIEF DESCRIPTION OF THE DRAWINGS

The accompanying figures, where like reference numerals refer to identical or functionally similar elements throughout the separate views, together with the detailed description below, are incorporated in and form part of the specification, and serve to further illustrate aspects of concepts that include the claimed systems and methods, and explain various principles and advantages of those embodiments.

FIG. 1 illustrates a robotic arm system for moving an object to or from the circuit board in accordance with some embodiments.

FIG. 2 illustrates an end effector of the system of FIG. 1 in accordance with some embodiments.

FIG. 3 is a flow chart illustrating a method implemented by the system of FIG. 1 in accordance with some embodiments.

FIG. 4 is a schematic block diagram of an electronic controller of the system of FIG. 1, in accordance with some embodiments.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of aspects illustrated.

The apparatus and method components have been represented where appropriate by conventional symbols in the drawings, showing only those specific details that are pertinent to understanding the aspects so as not to obscure the disclosure with details that will be readily apparent to those of ordinary skill in the art having the benefit of the description herein.

### DETAILED DESCRIPTION

Before any aspects are explained in detail, it is to be understood that the examples presented herein are not limited in their application to the details of construction and the arrangement of components set forth in the following description or illustrated in the drawings. Aspects may be practiced or carried out in various ways.

Also, it is to be understood that the phraseology and terminology used herein is for the purpose of description and should not be regarded as limiting. The terms “mounted,” “connected” and “coupled” are used broadly and encompass both direct and indirect mounting, connecting and coupling. Further, “connected” and “coupled” are not restricted to physical or mechanical connections or couplings, and can include electrical connections or couplings, whether direct or indirect. Also, electronic communications and notifications may be performed using any known means including wired connections, wireless connections, etc.

It should also be noted that a plurality of hardware and software-based devices, as well as a plurality of different structural components may be used to implement the aspects presented herein. Some aspects may include hardware, software, and electronic components or modules that, for purposes of discussion, may be illustrated and described as if the majority of the components were implemented solely in hardware. However, one of ordinary skill in the art, and based on a reading of this detailed description, would recognize that, in at least one aspect, the electronic based aspects may be implemented in software (for example, stored on non-transitory computer-readable medium) executable by one or more electronic processors. Therefore, it should be noted that a plurality of hardware and software-based devices, as well as a plurality of different structural components may be utilized to implement the aspects presented. For example, “control units” and “controllers” described in the specification can include one or more electronic processors, one or more memory modules including non-transitory computer-readable medium, one or more input/output interfaces, and various connections (for example, a system bus) connecting the components.

For ease of description, some of the example systems presented herein are illustrated with a single example of each of its component parts. Some examples may not describe or illustrate all components of the systems. Other aspects may include more or fewer of each of the illustrated components, may combine some components, or may include additional or alternative components.

A circuit board of this disclosure may have a plurality of capacitors that may be placed in various positions on the circuit board to tune the output of the circuit board to substantially match a desired output waveform. Tuning the capacitors on the circuit board may require a trial and-error process of iteratively placing an object on varying locations of the circuit board. A robot of this disclosure may be suitable to pick up an object and place the object on a circuit board. The robot of this disclosure may further be suitable to pick up the object from the circuit board and place the object back onto the circuit board at a second desired location. It is appreciated that a robot of this disclosure would be well suited to pick up and place objects on a circuit board for purposes other than tuning. Examples may include, for example, integrated circuit chip placement or relocation. In some embodiments, the robot may use vacuum pressure to pick up the object with a tuning tip and expel air through the tuning tip to place the object. In some embodiments, electrostatic buildup may occur on the object which may cause the object to adhere to nearby surfaces. In some embodiments, the vacuum pressure required to pick up the object must be sufficient to overcome any adhesive forces. Adhesive forces may be caused by, for example, electrostatic buildup in the object, moisture, or mechanical interactions with nearby surfaces which cause the object to adhere to various surfaces. In some embodiments, the expulsion pressure should be sufficient to overcome any adhesive forces that may cause the object to adhere to the tuning tip.

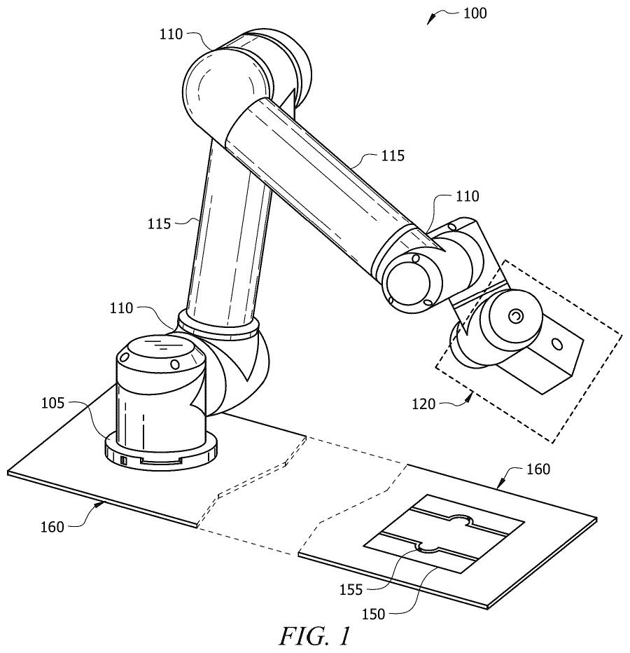

FIG. 1 illustrates an example of robotic arm system 100 in accordance with some embodiments. As described in more detail below, the robotic arm system 100 is configured to (via a user input or, in some embodiments, autonomously) pick up and place an object (for example, an object 155) on at a particular location on a surface (for example, a location on a circuit board 150 disposed on a surface of a structure 160). In the illustrated example, the robotic arm system 100 includes a base 105 for coupling (or mounting) the robotic arm system 100 to a stable surface of a structure (for example, structure 160). Base 105 represents any suitable object to support the robotic arm system 100. Base 105 may be made out of steel, aluminum, plastic, or any other suitable material to provide the appropriate support for the robotic arm system 100. In the illustrated embodiment, base 105 is positioned on the structure 160. In some embodiments, base 105 may be securely mounted to the structure 160. The structure 160 may include a table, countertop, portable stand, or any other suitable structure to provide appropriate support for the robotic arm system 100 and for circuit board 150. In some embodiments, the structure 160 is oriented horizontally, vertically, or at any angle. In some embodiments, the base is oriented horizontally, vertically, or at any angle.

It should be understood that, although both the robotic arm system 100 and the circuit board 150 are both disposed on the same surface (structure 160) in the illustrated example, it should be understood that, in some embodiments, the robotic arm system 100 is coupled/mounted to a different surface than that of the structure 160. For example, the robotic arm system 100 may be mounted to a structure (not shown) above the structure 160 including the circuit board 150. In some embodiments, the structure 160 is used as a reference point for the operation of the robotic arm system 100.

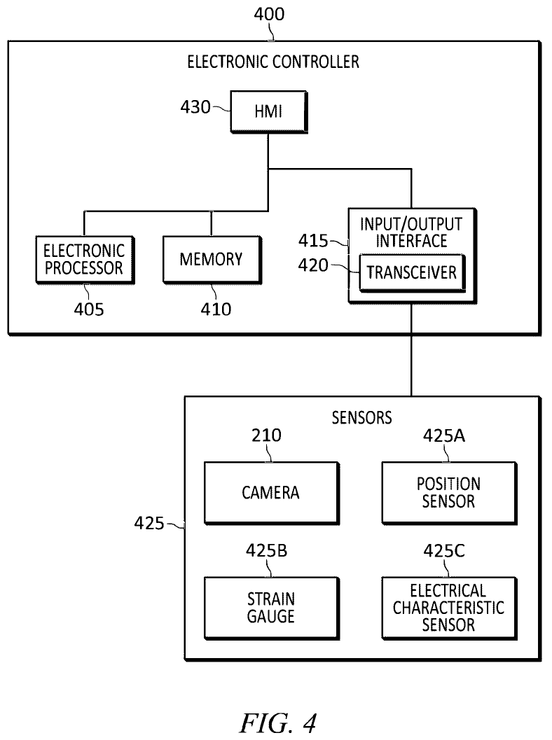

The robotic arm system 100 includes one or more joints 110, one or more connecting arms 115, and an end effector 120. The robotic arm system 100 additionally includes an electronic controller 400 illustrated in and described in more detail below with respect to FIG. 4.

As illustrated in FIG. 1, each joint 110 provides for a respective degree of motion of the robotic arm system 100. The joint 110 is a suitable electrically-driven mechanical joint (for example, rotary joints, ball-and socket joints, etc.) that allows the robotic arm system 100 to move freely in multiple degrees of motion. The joints 110 of the robotic arm system 100 may be the same type of joint or different types of joints. The robotic arm system 100 (in particular, the electronic controller 400 described in more detail below with respect to FIG. 4) is configured to individually adjust each joint 110 to move the end effector 120. The joint 110 allows for rotational motion, linear motion, or a combination of both of the robotic arm system 100. Each of the joints 110 is adjusted via a motor (not shown) driven according to commands from the electronic controller 400 to adjust the joint 110 a desired angular distance. In some examples, the system 100 includes one or more position sensors (for example, position sensors 425A of FIG. 4) configured to measure a relative position of one or more components of the robotic arm system 100. The sensors 425A, for example are configured to measure a relative position of a respective joint 110 (for example, an angular position or displacement within the range of motion of the particular joint). The electronic controller 400 may use the measurements to determine, among other things, a position of the end effector 120 (for example, relative to the structure 160, circuit board 150, and/or the object 155).

In some embodiments, one joint 110 directly abuts another joint 110. One joint 110 may be coupled to another joint 110 with connecting arm 115. The connecting arm 115 is any suitable mechanical component that connects to at least one joint 110. The connecting arm 115 may be comprised of steel, aluminum, plastic, or any other suitable material to connect joints 110. The connecting arm 115, in some embodiments, includes a hollow portion configured to house hardware (for example, electrical cables for power and/or communications between electrical components of the system 100).

The end effector 120 represents any suitable electrically-driven mechanical device configured to grip and handle an object (for example, the object 155) attached to an end of a joint 110 (as illustrated in FIG. 1) or, in some embodiments, a connecting arm 115 of the robotic arm system 100. As described in more detail below, the robotic arm system 100 is configured to pick up and place the object 155 (for example, on a circuit board 150) via the end effector 120. In some embodiments, the robotic arm system 100 is configured to place the object 155 on the circuit board 150 within 300 microns of a desired/predefined placement location.

The end effector 120 is configured to, via commands from the electronic controller 400, pick up the object 155 (for example, from a waffle pack/waffle pack tray (not shown) or a location on the circuit board 150) and place it on circuit board 150. In some embodiments, the end effector 120 is configured to pick up object 155 from a location on circuit board 150 and place object 155 either at the same location on circuit board 150 or a different location on circuit board 150.

The circuit board 150 is configured to receive and support the object 155 at one or more locations/positions on the circuit board 150. In some embodiments, the layout of circuit board 150 includes multiple designated sites, pads, and/or plated through-holes (PTHs) configured to receive the object 155. In some embodiments, the circuit board 150 is a printed circuit board (PCB) designed for, for example, radio frequency (RF) applications, signal processing, or other electronic purposes. The circuit board 150 may be configured to provide an output which may be measured (for example, as a waveform) via one or more sensors (for example, sensors 402 of the controller 400 of FIG. 4). The circuit board 150, in some aspects, is configured to accommodate a plurality of objects 155.

The object 155 may represent any suitable material or IC chip that may be used to electrically connect one or more other components on circuit board 150 or may serve as a tuning capacitor on circuit board 150. The object 155 may be, for example, a capacitor, resistor, inductor, or other passive or active electronic component. In some embodiments, the object 155 is made from alumina (ceramic), aluminum, copper, nickel, or any other suitable material for creating an electrical connection. In some embodiments, the object 155 is plated with a material such as gold, tantalum nitride, or titanium nitride. In some embodiments, the object 155 is a substantially rectangular shape and a relatively thin thickness. In some embodiments, the object 155 is substantially rectangular shaped having rectangular dimensions and a thickness dimension. The rectangular dimensions of object may be, for example, 20 mils (where a mil is one thousandth of an inch) by 30 mils. In some embodiments, the rectangular dimensions of object 155 is any desired combination of length and width between 10 mils by 10 mils to 40 mils by 40 mils. In some embodiments, the object 155 has a combination of length and width over 40 mils by 40 mils or under 10 mils by 10 mils. In some embodiments, the thickness dimension of the object 155 is or is at least 0.08 mils.

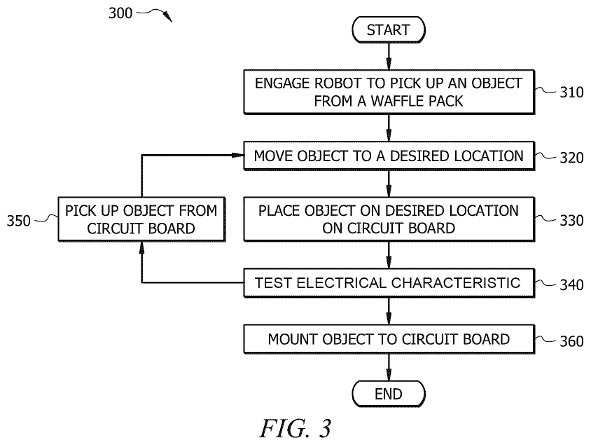

The particular placement of the object 155 on the circuit board 150 may affect one or more electrical characteristics of the circuit board 150 (in particular, the circuit thereof) (for example, the radio frequency (and/or range) in which the circuit of the circuit board 150 is configured to transmit and/or receive at). As described in more detail below, in some aspects, the system 100 is configured to, following placement of the object 155 onto the circuit board 150, determine, based on a measurement of an electrical characteristic of the circuit board 150 via one or more electrical characteristic sensors 425C (FIG. 4) configured to measure the electrical characteristic (for example, an voltage, current, RF response, etc.). Based on the measured electrical characteristic, the system 100 determines whether or not to reposition the object 155 and (in some embodiments, automatically) reposition the object 155 in response to determining that current location of the object 155 is not suitable (for example, the measured characteristic is outside of a predetermined/desired range or does not meet a predetermined threshold). As described in more detail below with respect to FIG. 3, during the tuning or testing process, one or more objects 155 may be placed on the circuit board 150 without being permanently affixed, such that their positions can be repeatedly adjusted by the robotic arm system 100. In some embodiments, the robotic arm system 100 may reposition objects 155 in response to real-time measurements from the sensors 402, enabling a closed-loop tuning process.

In an exemplary embodiment of operation, the robotic arm system 100 is initiated, via the electronic controller 400 of FIG. 4, to pick up object 155 using end effector 120 and then place the object 155 at a particular location on the circuit board 150. An electrical characteristic of the circuit board 150 (for example, an output of a circuit of the circuit board 150) may be tested via the electronic controller 400 to determine if the placement of the object 155 yields desirable results. In instances where the electronic controller 400 determines that measured electrical characteristic of the circuit board 150 is a non-desirable result, the robotic arm system 100 may be initiated (via a user input through the controller 400 or automatically via the controller 400) to pick up the object 155 from the circuit board 150 and place the object 155 at a different location on the circuit board 150. In some embodiments, the robotic arm system 100 may be configured to iteratively pick up the object 155 from the circuit board 150 and place the object 155 on the circuit board 150 until a desirable electrical characteristic of the circuit board 150 is determined.

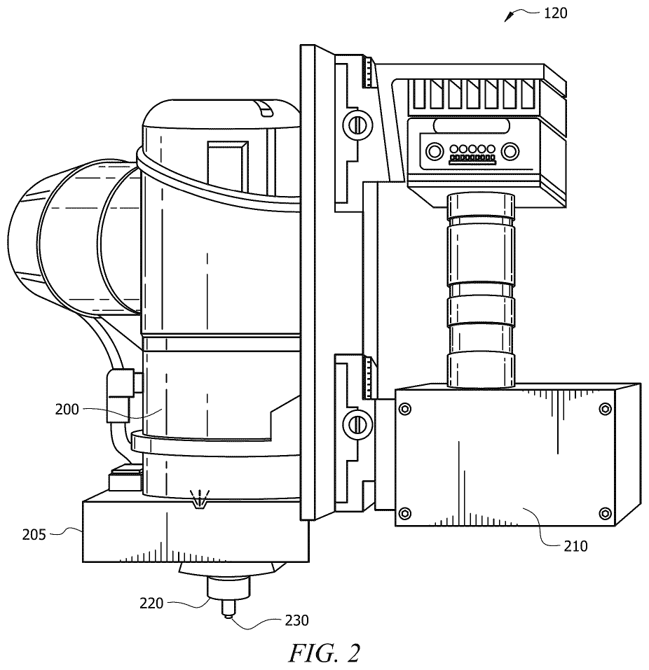

FIG. 2 illustrates an embodiment of the end effector 120 of the robotic arm system 100 in accordance with some embodiments. The end effector 120, in the illustrated example, includes an end effector mount 200, an air pressure device 205, a camera 210, a tuning tip fitting 220, and a tuning tip 230.

The end effector mount 200 is configured to receive and support a plurality of different components (for example, the air pressure device 205, tuning tip fitting 220, and tuning tip 230) to be coupled to the end effector 120. In some embodiments, the end effector mount 200 is made from steel, aluminum, plastic, or any other suitable material.

The air pressure device 205 is configured to suction (vacuum) or blow (expel) air with varying pressures. As illustrated, the air pressure device 205 may be coupled to the end effector mount 200. The air pressure device 205 is configured to selectively direct vacuum pressure and expulsion pressure through the tuning tip 230. For example, the air pressure device 205, in some embodiments, creates a vacuum pressure differential in a range between about 1 pound per square inch (psi) to about 15 psi. The air pressure device 205, in some embodiments, may create an expulsion pressure, for example, in a range between 10 psi and 45 psi.

The tuning tip fitting 220 is configured to support and couple the tuning tip 230 to the air pressure device 205. The tuning tip fitting 220 may be made from brass, steel, aluminum, plastic, or any other suitable material. The tuning tip fitting 220 is configured to support the pressures provided by the air pressure device 205.

The tuning tip 230 is coupled to the tuning tip fitting 220 and is configured to physically engage the object 155. The tuning tip 230 may be made from plastic, nitrile rubber, or any other suitable material. In some embodiments, the tuning tip 230 comprises graphite fibers (for example, to mitigate/prevent electrostatic buildup). In some embodiments, the tuning tip 230 is made from or comprises a coating of a rubber material (for example, to mitigate/prevent electrostatic buildup). In some embodiments, the tuning tip 230 is made from rubber.

In some embodiments, the tuning tip 230 has a generally rounded or conical shape with a flat surface. In such embodiments, the tuning tip 230 may comprise an opening (not shown) disposed within the flat surface and configured to expelled and vacuum air from and into the air pressure device 205. The opening of the tuning tip 230, in some embodiments, is smaller than that of an opening (not shown) of the tuning tip fitting 220 through which the air to and from the air pressure device 205 flows. The opening disposed within the flat surface may be circular and may have a diameter, for example, between 0.004 inches to 0.025 inches. In some embodiments, the opening disposed within the flat surface may be rectangular, square, or any other suitable shape. It should be understood that, in some embodiments, the diameter and/or particular shape of the tip fitting 220 may be different depending on the particular application of the system 100 (for example, based on the dimensions, thickness, shape, and/or other characteristics of the object 155). In some embodiments, the size of the tuning tip 230 is directly related to the size of the object 155. For example, in some embodiments, a tuning tip 230 with a smaller opening may be used for an object 155 with smaller dimensions. In some embodiments, the amount of air pressure provided through the tip 230 is directly related to the thickness of the object 155. For example, less air pressure for holding and releasing the object 155 may be used in instances where the object 155 has a smaller thickness. In such embodiments, one or more dimensions (size, thickness, etc.) of the object 155 may be determined by the system 100 automatically (for example, via one or more of the sensors 425 such as the camera 210) or provided by a user (via the HMI 430 described in more detail below) and the system 100 adjusts the air pressure through the tip 230 for performing the methods described herein accordingly based on the dimension(s). In some embodiments, the tuning tip fitting 220 is interchangeable with other types of tuning tip fittings with different openings. The system 100 may be configured to automatically switch between tuning tips (for example, based on the one or more determined dimensions of the object 150).

The tuning tip 230 is configured to engage the object 155 and apply a vacuum pressure from air pressure device 205 to pick up the object 155 and apply an expulsion pressure from air pressure device 205 to place the object 155. The tuning tip 230, in some embodiments, is flexible and acts as a spring when the tuning tip 230 is pressed onto the object 155 to pick up or place the object 155. The flexibility of tuning tip 230 may be used, for example, to improve consistency of the forced applied by tuning tip 230 to the object 155 when placing the object 155. In some embodiments, a desired level of force may be applied by the tuning tip 230 (for example, via a command from the electronic controller 400) to the object 155 when placing the object 155 to, for example, overcome a highly viscous epoxy. In some embodiments, the force applied by tuning tip 230 to place object 155 is up to 28 newtons. In some embodiments, the force may be limited by the structural limitations of circuit board 150. In some embodiments, a strain gauge (for example, strain gauge 425B of the sensors 425 of FIG. 4) may be affixed to the robotic arm system 100 to measure the force applied by the tuning tip 230.

The camera 210 is configured to capture one or more digital images (for example, static images, video, or both). The camera 210, in the illustrated example, is coupled to the end effector mount 200. The camera 210 is positioned such that the camera 210 captures images of the tuning tip 230 during operation of the robotic arm system 100. In some embodiments, the camera 210 is positioned such that the camera 210 captures images of circuit board 150 during operation of the robotic arm system 100. The camera 210, in some embodiments, may provide live image data to a monitor/display (for example, of the HMI 430 of the controller 400 of FIG. 4). In some embodiments, camera 210 provides live image data to a computer program either internally (within camera 210) or externally (a computer not within camera 210) for automated processing of the images captured by the camera 210. Image data from the camera 210 may be used, for example, to verify that the tuning tip 230 is placing the object 155 in the correct location on circuit board 150. In some embodiments, the camera 210 is used to verify the tuning tip 230 is in the correct location to pick up object 155 (for example, from a waffle pack or from circuit board 150). Verification of the tuning tip 230 location may either be manual (e.g., by a technician viewing live a live feed from camera 210 presented on the HMI 430 of FIG. 4) or automated (e.g., by live image processing performed by the electronic controller 400).

In an exemplary embodiment, the robotic arm system 100 is configured to pick up the object 155 using vacuum pressure created by the air pressure device 205, where the vacuum pressure is channeled through the tuning tip 230. The robotic arm system 100 may pick up the object 155 by pressing a flat surface of the tuning tip 230 against the object 155 such that a seal may be formed between the object 155 and tuning tip 230 to at least partially contain the vacuum pressure causing the object 155 to stick to the tuning tip 230. With the object 155 stuck to tuning tip 230 from the presence of vacuum pressure, the robotic arm system 100 may move object 155 to any desired location (for example, of the circuit board 150). In some embodiments of operation, the robotic arm system 100 may place the object 155 at the desired location by initiating an expulsion pressure from the air pressure devices 205 which may be channeled through the tuning tip 230. In some embodiments of operation, the expulsion pressure applied to place the object 155 may be sufficient to overcome adhesive forces (for example, surface friction, electrostatic, etc.) that cause the object 155 to stick to the tuning tip 230.

FIG. 4 is a schematic diagram of the electronic controller 400 according to some aspects. The electronic controller 400 includes an electronic processor 405 (for example, a microprocessor, application specific integrated circuit, etc.), a memory 410, and an input/output interface 415. The memory 410 may be made up of one or more non-transitory computer-readable media and includes at least a program storage area and a data storage area. The program storage area and the data storage area can include combinations of different types of memory, such as read-only memory (“ROM”), random access memory (“RAM”) (for example, dynamic RAM (“DRAM”), synchronous DRAM (“SDRAM”), etc.), electrically erasable programmable read-only memory (“EEPROM”), flash memory, or other suitable memory devices. The electronic processor 405 is coupled to the memory 410 and the input/output interface 415. The electronic processor 405 sends and receives information (for example, from the memory 410 and/or the input/output interface 415) and processes the information by executing one or more software instructions or modules, capable of being stored in the memory 410, or another non-transitory computer readable medium. The software can include firmware, one or more applications, program data, filters, rules, one or more program modules, and other executable instructions. The electronic processor 405 is configured to retrieve from the memory 410 and execute, among other things, software for autonomous and semi-autonomous control of the robotic arm system 100, and for performing methods as described herein.

The input/output interface 415 transmits to and receives information from devices external to the electronic controller 400 over one or more wired and/or wireless connections. The input/output interface 415 may include, for example, a transceiver 420. The input/output interface 415 receives input (for example, from one or more sensors 425 of the system 100), provides system output (for example, to one or more components of the robotic arm system 100 such as one or more joints 110, the air pressure device 205, the tuning tip 230, and the like), or a combination of both. The input/output interface 415 may also include other input and output mechanisms, which for brevity are not described herein and which may be implemented in hardware, software, or a combination of both.

The transceiver 420 includes a radio transceiver communicating data over one or more wireless communications networks (for example, cellular networks, satellite networks, etc.). Such communications networks may include wireless connections, wired connections, or combinations of both. The communications network may be implemented using a wide area network, for example, the Internet (including public and private IP networks), a Long Term Evolution (LTE) network, a Global System for Mobile Communications (or Groupe Spécial Mobile (GSM)) network, a Code Division Multiple Access (CDMA) network, an Evolution-Data Optimized (EV-DO) network, an Enhanced Data Rates for Global Evolution (EDGE) network, a 3G network, a 4G network, 5G network and one or more local area networks, for example, a Bluetooth™ network or Wi-Fi network, and combinations or derivatives thereof.

The transceiver 420 provides wireless communication within the system 100 using suitable network modalities (for example, Bluetooth™, near field communication (NFC), Wi-Fi™, and the like). Accordingly, the transceiver 420 communicatively couples the electronic controller 400 and other components of the system 100 with networks and electronic devices both inside and outside the system 100. For example, the electronic controller 400, using the transceiver 420, may be configured to communicate with a remote server (not shown) to send and receive data, commands, and other information (for example, fault notifications, log information, etc.). The transceiver 420 includes other components that enable wireless communication (for example, amplifiers, antennas, baseband processors, and the like), which for brevity are not described herein and which may be implemented in hardware, software, or a combination of both. Some instances include multiple transceivers or separate transmitting and receiving components (for example, a transmitter and a receiver) instead of a combined transceiver.

The sensors 425 include one or more sensors disposed at various locations within the robotic arm system 100 and are each configured to measure one or more particular characteristics of the robotic arm system 100. The sensors 425 include, for example, the camera 210 of FIG. 2. The sensors 425 may also include one or more of the position sensors 425A (for example, for measuring a relative position of one or more of the joints 110), pressure gauges 425B, and electrical characteristic sensors 425C. The electrical characteristic sensor 425C may be or include any type of sensor configured to measure electrical characteristics (for example, a voltage sensor, a current sensor, an RF sensor, and the like). The sensors 425 may further include additional sensors (including different types than those previously described) in some embodiments.

In some aspects, the electronic controller 400 includes a human machine interface (HMI) 430. The HMI 430 provides visual output, such as, for example, graphical indicators (i.e., fixed or animated icons), lights (for example, one or more light-emitting diodes (LEDs)), colors, text, images, combinations of the foregoing, and the like. The HMI 430 may include a suitable display mechanism (not shown) for displaying the visual output, such as, for example, a liquid crystal display (LCD) touchscreen, or an organic light-emitting diode (OLED) touchscreen), or other suitable mechanisms. In alterative aspects, the display screen may not be a touchscreen. In some instances, the HMI 430 displays a graphical user interface (GUI) (for example, generated by the electronic controller 400 and presented on a display screen) that enables a user to interact with one or more devices of the system 100 (for example, to provide commands to the system 100 to pick up and place the object 155 at a particular location on the circuit board 150). The HMI 430 may also provide audio output to the operator such as a chime, buzzer, voice output, or other suitable sound through a speaker included in the HMI 430 or separate from the HMI 430 (for example, to alert a user if the measured electrical characteristic of the circuit board 150 with a present placement of the object 155 is outside of the predetermined threshold or range). In some aspects, the HMI 430 provides a combination of visual, audio, and haptic outputs.

As described in more detail below, the electronic controller 400 is configured to use one or more machine learning and/or artificial intelligence methods (for example, to identify the object 155 within images captured by the camera 210, to improve accuracy in locating, picking up, moving, and/or placing the object 155 according to control of the joints 110 and/or the end effector 120). Machine learning generally refers to the ability of a computer program to learn without being explicitly programmed. In some instances, a computer program (for example, a learning engine) is configured to construct an algorithm based on inputs. Supervised learning involves presenting a computer program with example inputs and their desired outputs. The computer program is configured to learn a general rule that maps the inputs to the outputs from the training data it receives. Example machine learning engines include decision tree learning, association rule learning, artificial neural networks, classifiers, inductive logic programming, support vector machines, clustering, Bayesian networks, reinforcement learning, representation learning, similarity and metric learning, sparse dictionary learning, and genetic algorithms. Using these approaches, a computer program can ingest, parse, and understand data and progressively refine algorithms for data analytics and/or mechanical operation.

It should be understood that although FIG. 4 illustrates only a single electronic processor 405, memory 410, and input/output interface 415, alternative aspects of the electronic controller 400 may include multiple processors, memory modules, and/or input/output interfaces. It should also be noted that the system 100 may include other electronic controllers, each including similar components as, and configured similarly to, the electronic controller 400. In some instances, the electronic controller 400 is implemented partially or entirely on a semiconductor (for example, a field-programmable gate array [“FPGA”] semiconductor) chip. Similarly, the various modules and controllers described herein may be implemented as individual controllers, as illustrated, or as components of a single controller. In some instances, a combination of approaches may be used.

FIG. 3 is a flow chart illustrating an embodiment of a method 300 of operating a robot such as the robotic arm system 100 illustrated in FIGS. 1-2. As an example, the method 300 is described as being performed by the electronic controller 400 and, in particular, the electronic processor 405. However, it should be understood that in some instances, portions of the method 300 may be performed by other devices or subsystems of the system 100.

In some embodiments, the electronic controller 400 performs one or more blocks of the method 300 autonomously (without input from a user). For example, in some embodiments, the electronic controller 400 performs at least blocks 310, 320, 330, 340, and 350 automatically. Alternatively, in some aspects, the electronic controller 400 performs the method 300 with user input (for example, at one or more of block 310, 320, 330, 340, and/or 350).

As illustrated in FIG. 3, method 300 may be initiated at block 310. Alternatively, the method 300 may be preceded by some other block or may be initiated as a later block. At block 310, the electronic processor 405 picks up an object (for example, object 155) via the end effector 120 (for example, from a waffle pack or from a first location on the circuit board 155). The electronic processor 405 picks up the object 155, for example, by aligning the tuning tip 230 with the object 155 and pressing the tuning tip 230 against the object 155 while also applying vacuum pressure provided by air pressure device 205 which may be channeled through tuning tip 230 and applied to the object 155. Vacuum pressure applied to the object 155 may be sufficient to overcome adhesive forces attracting object 155 to the waffle pack/circuit board 155. In some embodiments, during block 310, the electronic processor 405 verifies the location of the tuning tip 230 in relation to the object 155 according to image data from the camera 210.

At block 320, the electronic processor 405 moves the object 155, via the end effector 120, to a desired location. In some embodiments, the desired location is on the circuit board 150. The electronic processor 405 may maintain the vacuum pressure from air pressure device 205 against the object 155 while moving the object 155. In some embodiments, during block 320, the electronic processor 405 uses image data from one or more of the sensors 425 (for example, the camera 210) to verify the location of the object 155 in relation to one or more other components such as the circuit board 150.

At block 330, the electronic processor 405 engages the end effector 120 to place the object 155 on the circuit board 150. In some embodiments, in placing the object 155, the electronic processor 405 channels an expulsion pressure from the air pressure device 205 through tuning tip 230 to overcome adhesive forces between the object 155 and the tuning tip 230 which may otherwise cause the object 155 to stick to the tuning tip 230. In some embodiments, during block 330, the electronic processor 405 uses data from one or more of the sensors 425 (for example, image data from the camera 210) to verify proper placement of object 155 on the circuit board 150.

For example, in releasing the object 155 from the tuning tip 230, the electronic processor 405 moves the tip 230 holding the object 155 downward towards a location on the circuit board 150. Upon detecting the object 155 make contact with the surface of the circuit board 150 (for example, based on relative position information of the end effector 120 derived from information from one or more of the sensors 425 or from information from one or more of the sensors 425 such as the strain gauge 425B (for example, approximately 28 Newtons)), the electronic processor 405 outputs a constant, regulated expulsion pressure from the air pressure device 205 (for example, approximately 50 psi). The particular control of the expulsion pressure allows for release of the object 155 from the tuning tip 230 as described above without accidentally displacing any other objects positioned on the circuit board 150. The particular amount of pressure/force applied to initially press the object 155 against the circuit board 150 while placing the object 155 may differ depending on the particular application (for example, the type of circuit board 150 (number of layers, thickness, material, and the like), the type of object 155, and the like) to, for example, prevent damage to the circuit board 150, the object 150, and/or the tuning tip 230. In some aspects, as mentioned above, the electronic processor 405 may utilize one or more machine learning and/or artificial intelligence algorithms to refine the controlled release of the object 155 from the tip 230.

At block 340, the electronic processor 405 tests an electrical characteristic of the circuit board 150 (for example, via the electrical characteristic sensor 425C) to determine whether the first location of the object 150 is suitable (for example, if the electrical characteristic of the circuit board 150 is meets a predetermined threshold or falls within a predetermined range (for example, a tolerance range)). In some embodiments, the electrical characteristic of the circuit board 150 is displayed (for example, as a waveform over time on an instrument such as a display of the HMI 430 of the electronic controller 400 or an additional device such as a network analyzer or oscilloscope communicatively coupled to the electronic controller 400). The electrical characteristic of the circuit board 150, in some embodiments, is compared to one or more predetermined values to determine whether the electrical characteristic is within a predetermined threshold or range. In some embodiments, the electrical characteristic is a radio frequency impedance of the circuit board 150. Accordingly, in such embodiments, the placement of the object 155 and resulting testing of the electrical characteristic of the circuit board 150 may be considered a radio frequency impedance tuning of the circuit board 150.

In instances where the electronic processor 405 determines that the first location of the object 150 is not suitable (for example, the electrical characteristic of the circuit board 150 does not meet the predetermined threshold/fall within the predetermined range), the method 300 proceeds to block 350. In instances where the electrical characteristic of the circuit board 150 falls within the predetermined threshold/range, the method 300 may end (or, in some embodiments, begin again at block 310 with another object 155). Alternatively, in some embodiments, in instances where the location is determined to be suitable (for example, the electrical characteristic of the circuit board 150 falls within the predetermined range and/or meet the predetermined threshold), the method 300 proceeds to block 360.

At block 350, the electronic processor 405 picks up the object 155 from the circuit board 150 via the end effector 120. The electronic processor 405 may pick up the object 155 by aligning the tuning tip 230 with the object 155 and pressing the tuning tip 230 against the object 155 while also applying vacuum pressure from the air pressure device 205, which may be channeled through the tuning tip 230 and applied to the object 155. The electronic processor 405 controls the vacuum pressure applied to object 155 to overcome adhesive forces attracting the object 155 to the circuit board 150 while being small enough to not accidentally displace any other objects positioned on the circuit board 150. In some embodiments, during block 350, the electronic processor 405 uses data from one or more of the sensors 425 (for example, image data from the camera 210) to verify the location of the tuning tip 230 in relation to the object 155. The method 300 then returns to block 320.

At block 360, the object 155 is secured to the circuit board 150. For example, in some embodiments, an epoxy and/or solder may be applied accordingly to securely mount the object 155 to circuit board 150. It should be appreciated that any suitable type of epoxy may be used to secure object 155 to circuit board 150. In some embodiments, the system 100 performs the securing of the object 155 to the circuit board 150 autonomously. In some aspects, the system 100 performs block 360 according to one or more commands from a user (received, for example, via the HMI 430). In some embodiments, block 360 is performed by the robotic arm system 100 or another robotic arm system.

In some embodiments, the electronic processor 405 utilizes one or more machine learning and/or artificial intelligence algorithms to refine and improve performance at one or more blocks of the method 300. For example, the electronic processor 405 may utilize one or more artificial intelligence algorithms to determine where to place the object after picking up the object at block 350 (for example, by determining one or more locations in which the resulting electrical characteristic of the circuit board 150 will not fall outside of the predetermined threshold/range). Such algorithms may advantageously reduce the number of iterations of relocating the object 155 in the method 300.

In the foregoing specification, specific aspects have been described. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of present teachings.

Moreover, in this document, relational terms such as first and second, top and bottom, and the like may be used solely to distinguish one entity or action from another entity or action without necessarily requiring or implying any actual such relationship or order between such entities or actions. The terms “comprises,” “comprising,” “has,” “having,” “includes,” “including,” “contains,” “containing” or any other variation thereof, are intended to cover a non-exclusive inclusion, such that a process, method, article, or apparatus that comprises, has, includes, contains a list of elements does not include only those elements but may include other elements not expressly listed or inherent to such process, method, article, or apparatus. An element proceeded by “comprises . . . a,” “has . . . a,” “includes . . . a,” or “contains . . . a” does not, without more constraints, preclude the existence of additional identical elements in the process, method, article, or apparatus that comprises, has, includes, contains the element.

Unless the context of their usage unambiguously indicates otherwise, the articles “a,” “an,” and “the” should not be interpreted as meaning “one” or “only one.” Rather these articles should be interpreted as meaning “at least one” or “one or more.” Likewise, when the terms “the” or “said” are used to refer to a noun previously introduced by the indefinite article “a” or “an,” “the” and “said” mean “at least one” or “one or more” unless the usage unambiguously indicates otherwise.

The terms “substantially,” “essentially,” “approximately,” “about” or any other version thereof, are defined as being close to as understood by one of ordinary skill in the art, and in one non-limiting aspect the term is defined to be within 10%, in another aspect within 5%, in another aspect within 1% and in another aspect within 0.5%. The term “coupled” as used herein is defined as connected, although not necessarily directly and not necessarily mechanically. A device or structure that is “configured” in a certain way is configured in at least that way but may also be configured in ways that are not listed.

Also, it should be understood that the illustrated components, unless explicitly described to the contrary, may be combined or divided into separate software, firmware, and/or hardware. For example, instead of being located within and performed by a single electronic processor, logic and processing described herein may be distributed among multiple electronic processors. Similarly, one or more memory modules and communication channels or networks may be used even if embodiments described or illustrated herein have a single such device or element. Also, regardless of how they are combined or divided, hardware and software components may be located on the same computing device or may be distributed among multiple different devices. Accordingly, in this description and in the claims, if an apparatus, method, or system is claimed, for example, as including a controller, control unit, electronic processor, computing device, logic element, module, memory module, communication channel or network, or other element configured in a certain manner, for example, to perform multiple functions, the claim or claim element should be interpreted as meaning one or more of such elements where any one of the one or more elements is configured as claimed, for example, to make any one or more of the recited multiple functions, such that the one or more elements, as a set, perform the multiple functions collectively. Regardless of how they are combined or divided, hardware and software components may be located on the same computing device or may be distributed among different computing devices connected by one or more networks or other suitable connections or links.

Thus, in the claims, if an apparatus or system is claimed, for example, as including an electronic processor or other element configured in a certain manner, for example, to make multiple determinations, the claim or claim element should be interpreted as meaning one or more electronic processors (or other element) where any one of the one or more electronic processors (or other element) is configured as claimed, for example, to make some or all of the multiple determinations collectively. To reiterate, those electronic processors and processing may be distributed.

It will be appreciated that some embodiments may be comprised of one or more generic or specialized processors (or “processing devices”) such as microprocessors, digital signal processors, customized processors and field programmable gate arrays (FPGAs) and unique stored program instructions (including both software and firmware) that control the one or more processors to implement, in conjunction with certain non-processor circuits, some, most, or all of the functions of the method and/or apparatus described herein. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used.

Moreover, an embodiment can be implemented as a computer-readable storage medium having computer readable code stored thereon for programming a computer (e.g., comprising a processor) to perform a method as described and claimed herein. Any suitable computer-usable or computer readable medium may be utilized. Examples of such computer-readable storage mediums include, but are not limited to, a hard disk, a CD-ROM, an optical storage device, a magnetic storage device, a ROM (Read Only Memory), a PROM (Programmable Read Only Memory), an EPROM (Erasable Programmable Read Only Memory), an EEPROM (Electrically Erasable Programmable Read Only Memory) and a Flash memory. In the context of this document, a computer-usable or computer-readable medium may be any medium that can contain, store, communicate, propagate, or transport the program for use by or in connection with the instruction execution system, apparatus, or device.

What is claimed is:

1. A robotic arm system configured to iteratively pick up and place an object on a circuit board, the system comprising:
a sensor configured to measure an electrical characteristic of the circuit board;
an end effector including a tuning tip configured to physically engage the object; and
an electronic processor configured to
pick up, via the end effector, the object,
move, via the end effector, the object to a first location of the circuit board,
place, via the end effector, the object on the first location of the circuit board,
test, via information from the sensor, a first electrical characteristic of the circuit board, and
pick up, via the end effector, the object from the first location in response to determining that, based on the testing of the first electrical characteristic, the first location is not suitable.

2. The system of claim 1, wherein the electronic processor is configured to perform at least one selected from the group consisting of picking up the object, moving the object, placing the object, and testing the electrical characteristic of the circuit board autonomously.

3. The system of claim 1, wherein the electronic processor is configured to autonomously pick up the object, move the object, place the object, and test the electrical characteristic of the circuit board.

4. The system of claim 1, wherein the tuning tip is flexible and acts as a spring when pressed onto the object to pick up or place the object.

5. The system of claim 4, wherein the tuning tip is configured to apply a vacuum pressure to pick up the object and apply an expulsion pressure to place the object.

6. The system of claim 5, wherein the electronic processor is configured to adjust the vacuum pressure based on a dimension of the object.

7. The system of claim 1, wherein the electronic processor is further configured to
move, via the end effector, the object to a second location of the circuit board,
place, via the end effector, the object on the second location of the circuit board,
test, via information from the sensor, a second electrical characteristic of the circuit board, and
pick up, via the end effector, the object from the second location in response to determining that, based on the testing of the second electrical characteristic, the second position is not suitable.

8. The system of claim 1, wherein the object has a length and width between 10 mils by 10 mils to 40 mils by 40 mils.

9. The system of claim 1, wherein the electronic processor picks up the object from a waffle pack.

10. The system of claim 1, wherein the electronic processor picks up the object from the circuit board.

11. A method for operating robotic arm system configured to iteratively pick up and place an object on a circuit board, the method comprising:
picking up, via an end effector including a tuning tip configured to physically engage the object, the object,
moving, via the end effector, the object to a first location of the circuit board,
placing, via the end effector, the object on the first location of the circuit board,
testing, via information from a sensor configured to measure a first electrical characteristic of the circuit board, an electrical characteristic of the circuit board, and
picking up, via the end effector, the object from the first location in response to determining that, based on the testing of the first electrical characteristic, the first location is not suitable.

12. The method of claim 11, wherein at least one selected from the group consisting of picking up the object, moving the object, placing the object, and testing the electrical characteristic of the circuit board is performed autonomously.

13. The method of claim 11, wherein picking up the object, moving the object, placing the object, and testing the electrical characteristic of the circuit board are performed autonomously.

14. The method of claim 11, wherein the tuning tip is flexible and acts as a spring when pressed onto the object to pick up or place the object.

15. The method of claim 11, wherein the tuning tip is configured to apply a vacuum pressure to pick up the object and apply an expulsion pressure to place the object.

16. The method of claim 15, wherein the vacuum pressure is adjusted based on a dimension of the object.

17. The method of claim 11, the method further comprising:
moving, via the end effector, the object to a second location of the circuit board,
placing, via the end effector, the object on the second location of the circuit board,
testing, via information from the sensor, a second electrical characteristic of the circuit board, and
picking up, via the end effector, the object from the second location in response to determining that, based on the testing of the second electrical characteristic, the second location is not suitable.

18. The method of claim 11, wherein the object has a length and width between 10 mils by 10 mils to 40 mils by 40 mils.

19. The method of claim 11, wherein the object is picked up from a waffle pack.

20. The method of claim 11, wherein the object is picked up from the circuit board.
